(19) United States
(12) Patent Application Publication
(10) Pub. No.: US 2007/0051533 A1
(43) Pub. Date: Mar. 8, 2007

(54) Optical electronics integrated semiconductor package

(76) Inventor: Shih-Ping Hsu, Hsin-chu (TW)

Correspondence Address: SAWYER LAW GROUP LLP, P O BOX 51418, PALO ALTO, CA, 94303, US

(21) Appl. No.: 11/508,510

(22) Filed: Aug. 23, 2006

(30) Foreign Application Priority Data
Sep. 5, 2005 (TW) 094130252

(51) Int. Cl. H05K 1/00

(52) U.S. Cl. 174/250

(57) ABSTRACT

An optical electronics integrated semiconductor package is proposed. A circuit board with at least one through opening and at least one optical component with an active surface and a non-active surface opposite to the active surface are provided. The active surface has an optical activated area facing the through opening of the circuit board. A plurality of connecting pads are disposed on the active surface of the optical component and are electrically connected to the circuit board. The circuit board has a dielectric layer, a circuit layer and the through opening. The optical component is integrated with the circuit board by connecting the electrical connection structure in the dielectric layer to the connecting pads of the optical component.

### CROSS-REFERENCE TO RELATED APPLICATIONS

This application claims benefit under 35 USC 119 of Taiwan Application No. 094130252, filed on Sep. 5, 2005.

### FIELD OF THE INVENTION

The present invention relates to optical electronics integrated semiconductor packages, and more particularly, to a semiconductor package integrated with optical conductive chips and circuit structures.

### BACKGROUND OF THE INVENTION

As the technological development of semiconductors advances, demands for miniaturized packaging and larger data storage capacity have also intensified along the way. In addition to that, because the data processing capacity is constantly increasing, if data units of the same size can be processed at the fastest speed possible in a given unit of time, then data can be processed more efficiently. The most straightforward method for raising the processing speed of semiconductors is to increase its usage frequency, but when the clock rates more then Gb/s, problems like power dissipation caused by high wattage, signal time delay, and electromagnetic interference (EMI) also arise, which will impede the production of semiconductors with high performance. This problem has been made even more severe because the traditional medium for data signal transfer is copper circuit, which cannot achieve higher conductivity due to its intrinsically limited conducting property, thus its signal transmission speed cannot be elevated by the method of increasing its conductivity.

Moreover, the signal transmission structure made of metal circuits is more susceptible to the interference of external noises or internal circuits during signal transmitting, which in turn leads to erroneous signals being transferred. Therefore, the signal transmitting structure has to be equipped with adequate protective measures to prevent the interference mentioned above from affecting signals, and this phenomenon is especially obvious in high-frequency application. The protective measures will result in increased difficulty to the designs of circuit and additional structures, which will in turn raise the costs of design and production, and cannot improve the current situation.

The traditional method of signal transmitting is analog transmission, which works by charging conductor with electrical currents, but the current method for processing signals inside circuits is the digital processing method, which can easily distort signals when one type of signal is converted to the other during signal transfer.

In order to resolve the disadvantages resulted from the traditional method of analog signal transmission, the new technology uses optical signal to replace electrical signal for signal transmission, and the most palpable advantage by such change is better quality in signal transmission, since the optical signal is almost unsusceptible to interference of electromagnetic waves and is thus not distorted as much. As a result, there is no need to design a structure for preventing the interference of electromagnetic waves, and this helps reduce the costs of design and production. Therefore, using optical signal for signal transmission has become the main aim for future development.

In the prior arts, the optical signal transmission requires signal processing components such as optical fibers, optical connectors, optical/electrical converters, and electrical/optical converters for digital data transfer to proceed, but optical alignment system of high precision is large in size and hence can hamper the developmental trend of miniaturization.

Furthermore, when precise alignment is carried out by the use of optical connector with optical fiber, the high precision aligning equipment is also needed for the transmission of optical signal to proceed due to the lower performance of automatic production. In addition, it is also necessary to carry out aligning and connecting by manual labor, which leads to increased production costs and reduced productivity.

Therefore, the most urgent issue for the industry is to provide an optical electronics integrated semiconductor package that can meet the demand of miniaturization, reduce loss of signal during signal transmitting, shorten conductivity pathway, decrease noises, elevate electrical quality, increase connection alignment, lower production costs, and raise productivity.

### SUMMARY OF THE INVENTION

In light of the shortcomings described above, the primary objective of the present invention is to provide an optical electronics integrated semiconductor package that can meet the demand of miniaturization for electronic devices.

Another objective of the present invention is to provide an optical electronics integrated semiconductor package that can reduce loss of signal during signal transmitting, shorten conductivity pathway, decrease noises, and elevate electrical quality.

Another objective of the present invention is to provide an optical electronics integrated semiconductor package that can increase connecting alignment, so that the quality of signal transmitting can be raised.

A further objective of the present invention is to provide an optical electronics integrated semiconductor package that can lower production costs and raise productivity.

To accomplish the aforementioned and other objectives, the optical electronics integrated semiconductor package of the present invention is consisted of: a circuit board that has at least one dielectric layer and one circuit layer, and the circuit layer has a plurality of conductive structures that are formed in the dielectric layer, at least one through opening is also formed in the circuit board; at least one optical component with an active surface and a non-active surface opposite to the active surface, the active surface is disposed with an optical activated area and a plurality of connecting pads. The conductive structures of the above circuit layer are electrically connected to the connecting pads on the active surface of the optical component, so that the optical component and the circuit board are electrically and physically connected, and the optical activated area is corresponding the through opening of the circuit board. The circuit board is manufactured with circuits of either single layer or double layer, and the optical component can be either laser diode (LD), light emitting diode (LED), vertical cavity surface emitting laser (VCSEL), photodiode (PD), or photo sensor.

Additionally, there is an insulating protective layer formed on the outer surface of circuit layer in the circuit board, and a plurality of openings are also formed in the insulating protective layer to expose the parts of circuit layer that serve as electrical connecting pads. The electrical connecting pads of the circuit board are electrically and physically connected to a semiconductor chip or another optical component, thereby making the optical activated area on the active surface of another optical component correspond the opening of the circuit board, so that the optical components can directly transmit and receive optical signals.

In another embodiment, in which the optical electronics integrated semiconductor package is further comprised of at least one semiconductor chip that is electrically and physically connected to the circuit board, the semiconductor chip has an active surface and a non-active surface opposite to the active surface, and a plurality of electrode pads are disposed on the active surface. The circuit board has at least one dielectric layer, one circuit layer, and one through opening that penetrates the circuit board, and the circuit layer is electrically connected to the electrode pads located on the active surface of the semiconductor chip by a plurality of conductive structures formed in the dielectric layer.

In a further embodiment, the optical electronics integrated semiconductor package is further comprised of at least one flexible circuit board, whose electrical connection is extended outwardly from the circuit board.

Therefore, in the optical electronics integrated semiconductor package of the present invention, a circuit board is formed by disposing a plurality of openings upon the active surface of the optical component, so that the circuits of the circuit board are electrically connected to the connecting pads of the optical component directly; the optical activated area of the optical component is made corresponding the opening, thereby forming a optical electronics integrated semiconductor package that meets the demand of miniaturization for electronic devices. The integration of optical electronics can also improve electrical quality by shortening conductivity pathway and reducing loss of signal during signal transmit, as well as reducing noises. Additionally, the present invention also makes the circuits of the circuit board directly connect to the connecting pads of the optical component, which not only increases the connection alignment, but also elevates productivity by cutting production costs.

To provide a further understanding of the present invention, the following description and figures illustrate the embodiments of the present invention, it is to be understood that the description and figures are provided only for elucidating the present invention and not as limiting the scope of it.

### BRIEF DESCRIPTION OF THE DRAWINGS

The present invention can be more fully comprehended by reading the detailed description of the embodiments listed below, with reference made to the accompanying drawings, wherein:

FIG. 1 is the schematic cross-sectional view illustrating the first embodiment of the optical electronics integrated semiconductor package according to the present invention.

FIG. 2 is the schematic cross-sectional view illustrating the second embodiment of the optical electronics integrated semiconductor package according to the present invention.

FIG. 3 is the schematic cross-sectional view illustrating the third embodiment of the optical electronics integrated semiconductor package according to the present invention.

FIG. 4 is the schematic cross-sectional view illustrating the fourth embodiment of the optical electronics integrated semiconductor package according to the present invention.

### DETAILED DESCRIPTION OF THE INVENTION

The present invention relates generally to optical electronics integrated semiconductor packages, and more particularly, to a semiconductor package integrated with optical conductive chips and circuit structures.

The following description is presented to enable one of ordinary skill in the art to make and use the invention and is provided in the context of a patent application and its requirements. Various modifications to the s and the generic principles and features described herein will be readily apparent to those skilled in the art. Thus, the present invention is not intended to be limited to the embodiments shown, but is to be accorded the widest scope consistent with the principles and features described herein.

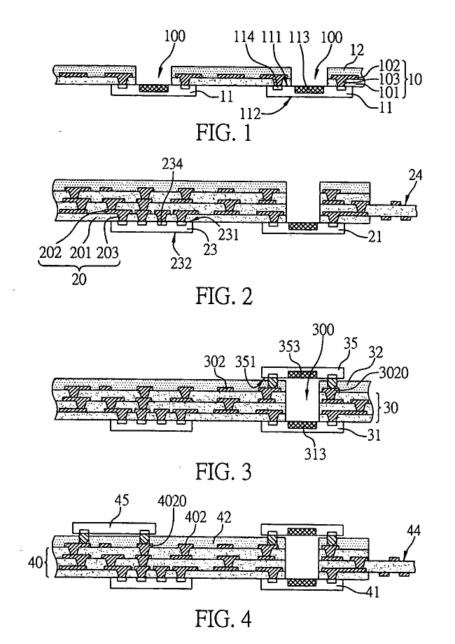

Referring to FIG. 1, which shows the schematic cross-sectional view of the optical electronics integrated semiconductor package in accordance with the first embodiment of the present invention.

As shown in the figure, the optical electronics integrated semiconductor package is composed of: a circuit board 10 that has at least one through opening 100, and at least one optical component 11 that has an active surface 111 and a non-active surface 112 opposite to the active surface 111; optical activated area 113 is disposed on active surface 111, so that optical component 11 and circuit board 10 are electrically and physically connected, thereby exposing optical activated area 113 through the through opening 100 of circuit board 10.

The optical component 11 has an active surface 111 and a non-active surface 112; an optical activated area 113 and a plurality of connecting pads 114 are located on the active surface 111 of optical component 11. The optical component 11 can be either LD, LED, VCSEL, PD, or photo sensor.

The circuit board 10 has at least one dielectric layer 101, one circuit layer 102 and one through opening 100 that penetrates circuit board 10. The circuit layer 102 is electrically connected to connecting pads 114 on active surface 111 of optical component 11 by a plurality of conductive structures 103 formed in dielectric layer 101, so that optical activated area 113 of optical component 11 is exposed through the through opening 100 of circuit board 10. As a result, the optical electronics integrated semiconductor package of the present invention is completed; this package can carry out signal transmitting via optical and electrical signals simultaneously, which in turn leads to improvement in the electrical property and multi-purpose functionality of electronic devices.

Furthermore, an insulating protective layer 12 is formed on the outer surface of circuit layer 102 of circuit board 10 in order to protect the circuit layer 102 underneath its cover.

In addition to that, it should be noted that the circuit board can be a selection between a circuit board with single-layer circuits or with multi-layer circuits; it is not restricted by the figure provided here.

Referring to FIG. 2, which illustrates the schematic cross-sectional view of the optical electronics integrated semiconductor package in accordance with the second embodiment of the present invention.

The optical electronics integrated semiconductor package of this embodiment is mostly identical to that of the first embodiment, the main difference is that in this case it is further comprised of at least one semiconductor chip 23, which is electrically and physically connected to circuit board 20 that integrated with optical component 21, and the semiconductor chip 23 is located on the same side with optical component 21 in the circuit board.

The semiconductor chip 23 has an active surface 231 and a non-active surface 232 opposite to active surface 231, a plurality of electrode pads 234 are disposed on active surface 231, and at least one circuit layer 202 is electrically connected to electrode pads 234 on active surface 231 of semiconductor chip 23 by a plurality of conductive structures 203 formed in dielectric layer 201; the circuit layer 202 is electrically connected to connecting pads 214 on active surface 211 of optical component 21 by a plurality of conductive structures 203 formed in dielectric layer 201, and the optical activated area 213 of optical component 21 is exposed through the through opening 200 of circuit board 20. As a result, the optical electronics integrated semiconductor package is simultaneously integrated with optical component 21 and semiconductor chip 23, which elevates the electrical functions of semiconductor package.

Additionally, the optical electronics integrated semiconductor package of this embodiment can be further comprised of at least one flexible circuit board 24, whose electrical connection extends outwardly from circuit board 20, thereby further extending the electrical functions of the optical electronics integrated semiconductor package.

Referring to FIG. 3, which depicts the schematic cross-sectional view of the optical electronics integrated semiconductor package according to the third embodiment of the present invention.

The optical electronics integrated semiconductor package of this embodiment is mostly identical to that of the previous embodiments; the major difference is that in this case, the optical electronics integrated semiconductor package is further comprised of a optical component 35, wherein the optical component 35 is electrically and physically connected to circuit board 30 that integrated with optical component 31.

An insulating protective layer 32 is formed on circuit layer 302 of circuit board 30, in which a plurality of openings are formed in insulating protective layer 32 to expose the parts of circuit layer 302 that serve as electrical connecting pads 3020, so that optical component 35 is electrically and physically connected to electrical connecting pads 3020 of circuit board 30 by conductive materials. The optical activated area 353 on active surface 351 of optical component 35 is corresponding opening 300 of the circuit board, so that it is also corresponding optical activated area 313 of optical component 31. In other words, optical component 31 and 35 are located on either side of opening 300 of circuit board 30 and correspond each other through opening 300, and thus signals from optical component 31 and 35 can be transmitted and received between the two optical components, by which the electrical functions of the semiconductor package is improved.

Referring to FIG. 4, which shows the schematic cross-sectional view of the optical electronics integrated semiconductor package according to the fourth embodiment of the present invention.

The optical electronics integrated semiconductor package of this embodiment is mostly identical to that of the previously described embodiments; the major difference is that in this case the optical electronics integrated semiconductor package is further comprised of a semiconductor chip 45 that is disposed on the circuit board integrated with optical component 41, wherein the outer circuit layer 402 of circuit board 40 is covered by a insulating protective layer 42, and a plurality of openings are formed in insulating protective layer 42 to expose the parts of circuit layer 402 that serve as electrical connecting pads 4020, so that semiconductor chip 45 is electrically and physically connected to electrical connecting pads 4020.

In addition, the optical electronics integrated semiconductor package of this embodiment is further comprised of at least one flexible circuit board 44, whose electrical connection extends outwardly from circuit board 40 and thereby further increasing the electrical functions of the semiconductor package.

Therefore, in the optical electronics integrated semiconductor package of the present invention, a circuit board with openings is formed on the active surface of an optical component, so that the circuits of the circuit board can be electrically connected to the connecting pads of the optical component directly. The optical activated area of the optical component is corresponding the opening, which can facilitate the production of an optical electronics integrated semiconductor package that satisfies the demand of miniaturization. The integration of optical electronics also improves electrical quality of the package by reducing noises and loss of signal during signal transfer and shortening conductivity pathway. In addition to that, this invention also makes the circuits of circuit board directly connect to connecting pads of optical component, thereby increasing connecting alignment, cutting production costs, and raising productivity.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. An optical electronics integrated semiconductor package, comprising:
a circuit board, which has at least one dielectric layer and one circuit layer, and the circuit layer has a plurality of conductive structures that are formed in the dielectric layer, at least one through opening is also formed in the circuit board; and
at least one optical component that has an active surface and a non-active surface opposite to the active surface, an optical activated area and a plurality of connecting pads are disposed on the active surface; the conductive structures of the above circuit layer are electrically connected to the connecting pads on the active surface of the optical component, so that the optical component and the circuit board are electrically and physically connected, and the optical activated area is corresponding the through opening of the circuit board.

2. The optical electronics integrated semiconductor package of claim 1, wherein the outer circuit layer of the circuit board is covered by an insulating protective layer.

3. The optical electronics integrated semiconductor package of claim 2, wherein a plurality of openings are formed in the insulating protective layer to expose the parts of circuit layer that serve as the electrical connecting pads, so that a semiconductor chip is electrically and physically connected to the electrical connecting pads.

4. The optical electronics integrated semiconductor package of claim 2, wherein a plurality of openings are formed in the insulating protective layer to expose the parts of circuit layer that serve as the electrical connecting pads, and another optical component is electrically and physically connected to the electrical connecting pads of the circuit board; the optical activated area on the active surface of the other optical component is corresponding the opening of the circuit board.

5. The optical electronics integrated semiconductor package of claim 4, wherein the optical activated area of the other optical component is corresponding the opening of the circuit board and opposite to the optical activated area of the optical component.

6. The optical electronics integrated semiconductor package of claim 1, wherein the circuit board can be a circuit board with either single-layer circuits or multi-layer circuits.

7. The optical electronics integrated semiconductor package of claim 1, wherein the optical component can be either laser diode (LD), light emitting diode (LED), vertical cavity surface emitting laser (VCSEL), photodiode (PD), or photo sensor.

8. The optical electronics integrated semiconductor package of claim 3, wherein the semiconductor chip has an active surface and a non-active surface opposite to the active surface; a plurality of electrode pads are located on the active surface, and the conductive structures of the circuit layer are electrically connected to the electrode pads.

9. The optical electronics integrated semiconductor package of claim 8, wherein the semiconductor chip is located on the same side with optical components in the circuit board.

10. The optical electronics integrated semiconductor package of claim 1, further comprising at least one flexible circuit board, which is electrically connected and its electrical connection extends outwardly from the circuit board.
